(19) United States
(12) Patent Application Publication
(10) Pub. No.: US 2014/0359401 A1
(43) Pub. Date: Dec. 4, 2014

(54) Field-Repair System and Method

(71) Applicant: HangZhou HaiCun Information Technology Co. Ltd., HangZhou (CN)

(72) Inventor: Guobiao ZHANG, Corvallis, OR (US)

(73) Assignee: HANGZHOU HAICUN INFORMATION TECHNOLOGY CO. LTD., HangZhou (CN)

(21) Appl. No.: 14/461,531

(22) Filed: Aug. 18, 2014

Related U.S. Application Data
(63) Continuation of application No. 13/597,220, filed on Aug. 28, 2012.
(60) Provisional application No. 61/529,923, filed on Sep. 1, 2011.

(51) Int. Cl. G11C 29/00; G06F 11/10

(52) U.S. Cl. CPC G11C 29/822; G06F 11/1068; G11C 29/785; G06F 2212/7209; G11C 2229/74
USPC 714/773

(57) ABSTRACT

The present invention discloses a field-repair system and method for three-dimensional mask-programmed memory (3D-MPROM). Most 3D-MPROM data are not checked in factory, but checked and repaired in field. The field-repair system comprises a playback device with a communicating means. Once the playback device detects bad data from the 3D-MPROM, it uses the communicating means to fetch good data to replace the bad data from a remote server, which stores at least a correct copy of the 3D-MPROM data.

### CROSS-REFERENCE TO RELATED APPLICATIONS

This is a continuation of an application “Field-Repair System and Method”, application Ser. No. 13/597,220, filed Aug. 28, 2012, which claims benefit of a provisional application “Field-Repair System and Method for Pre-Recorded Three-Dimensional Read-Only Memory”, Application Ser. No. 61/529,923, filed Sep. 1, 2011.

### BACKGROUND

1. Technical Field of the Invention

The present invention relates to the field of the integrated circuit, more particularly to mask-programmed read-only memory (mask-ROM).

2. Prior Arts

With the advent of three-dimensional mask-programmed read-only memory (3D-MPROM), the storage capacity of the mask-ROM greatly improves. U.S. Pat. No. 5,835,396 discloses a 3D-MPROM. It is a monolithic semiconductor memory. As illustrated in FIG. 1, a typical 3D-MPROM comprises a semiconductor substrate 0 and a 3-D stack 10 stacked above. The 3-D stack 10 comprises M (M2) vertically stacked memory levels (e.g., 10A, 10B). Each memory level (e.g., 10A) comprises a plurality of upper address lines (e.g., 2a), lower address lines (e.g., 1a) and memory cells (e.g., 5aa). Each memory cell stores n (n1) bits. Memory levels (e.g., 10A, 10B) are coupled to the substrate 0 through contact vias (e.g., 1av, 1av′). The substrate circuit OX in the substrate 0 comprises a peripheral circuit for the 3-D stack 10. Hereinafter, ×M×n 3D-MPROM denotes a 3D-MPROM comprising M memory levels with n bits-per-cell (bpc).

3D-MPROM is a diode-based cross-point memory. Each memory cell (e.g., 5aa) typically comprises a diode 3d. The diode can be broadly interpreted as any device whose electrical resistance at the read voltage is lower than that when the applied voltage has a magnitude smaller than or polarity opposite to that of the read voltage. The memory level 10A further comprises a data-coding layer 6A, i.e. a blocking dielectric 3b. It blocks the current flow between the upper and lower address lines. Absence or existence of a data-opening 6ca in the blocking dielectric 3b indicates the state of a memory cell. Besides the blocking dielectric 3b, the data-coding layer 6A could also comprise a resistive layer (referring to U.S. patent application Ser. No. 12/785,621) or an extra-dopant layer (referring to U.S. Pat. No. 7,821,080).

Inevitably, a manufactured mask-ROM contains faulty memory cells. In prior arts, a mask-ROM is factory-repaired, i.e. the data in the mask-ROM (i.e. the mask-ROM data) are checked and repaired in factory. As illustrated in FIG. 2, this factory-repair process is carried out in a tester and comprises the following steps: read data at address A (step 61); check the data (step 63); if no bad data are detected, increment the address A (step 65); otherwise, fetch the good data for the address A from the tester (step 67), and write the address A and the associated good data to a redundancy ROM (step 69). Apparently, any detected bad data are the data that cannot be corrected by any error-correcting means in the mask-ROM.

Factory-repair requires reading out all data in a mask-ROM. In the past, this is not difficult for the conventional mask-ROM, which stores a limited amount of data. However, this is very difficult for a large-capacity mask-ROM, more particularly for a 3D-MPROM. For a TB-scale 3D-MPROM, it could take days to read out all of its data. Such a long testing time makes the factory-repair prohibitively expensive. Furthermore, during the course of its use in the field, the mask-ROM may suffer additional failures due to aging of its memory cells. Apparently, factory-repair cannot repair the bad data caused by these failures.

### OBJECTS AND ADVANTAGES

It is a principle object of the present invention to provide a large-capacity mask-ROM, more particularly a 3D-MPROM, with a lower testing cost.

It is a further object of the present invention to provide a method to reduce the testing time and testing cost for a large-capacity mask-ROM, more particularly a 3D-MPROM.

It is a further object of the present invention to provide a method to repair the bad data caused by the aging of semiconductor memory cells during field use.

In accordance with these and other objects of the present invention, field-repair system and method are disclosed.

### SUMMARY OF THE INVENTION

The present invention discloses a field-repair system and method for a large-capacity mask-ROM, more particularly for a 3D-MPROM. The field-repair system comprises a playback device (e.g., cellular phone, internet TV, or computer) and a memory card containing at least a 3D-MPROM die (i.e. a 3D-MPROM card). Most of the 3D-MPROM data are not checked in factory, but checked and repaired in field, i.e. during the use of the playback device. A feature that distinguishes the present invention from prior arts is that the 3D-MPROM data are checked and repaired by a playback device, not by a tester. The playback device, which is a consumer device, is not on a par in price and complexity with a tester, which is an industrial equipment.

Field-repair takes full advantage of a communicating means (e.g., internet, WiFi and cellular communication means) of the playback device to communicate with a remote server, which stores a correct copy of the 3D-MPROM contents. During field use, an error-detecting means checks the data read out from the 3D-MPROM. When bad data are detected, the good data to replace the bad data are fetched from the remote server with the communicating means. Field-repair can significantly reduce the factory-testing time and lower the factory-testing cost.

### BRIEF DESCRIPTION OF THE DRAWINGS

FIG. 1 is a cross-sectional view of a 3D-MPROM;

FIG. 2 discloses a factory-repair process for a mask-ROM in prior arts;

FIG. 3 discloses a preferred field-repair system and its communication with a remote server;

FIGS. 4A-4B illustrate two preferred playback devices;

FIG. 5 is a flow chart showing a preferred testing/repair method;

FIG. 6 discloses more details of the preferred field-repair system;

FIG. 7 is a flow chart showing a preferred field-repair method;

FIG. 8 is cross-sectional view of a preferred 3D-MPROM card.

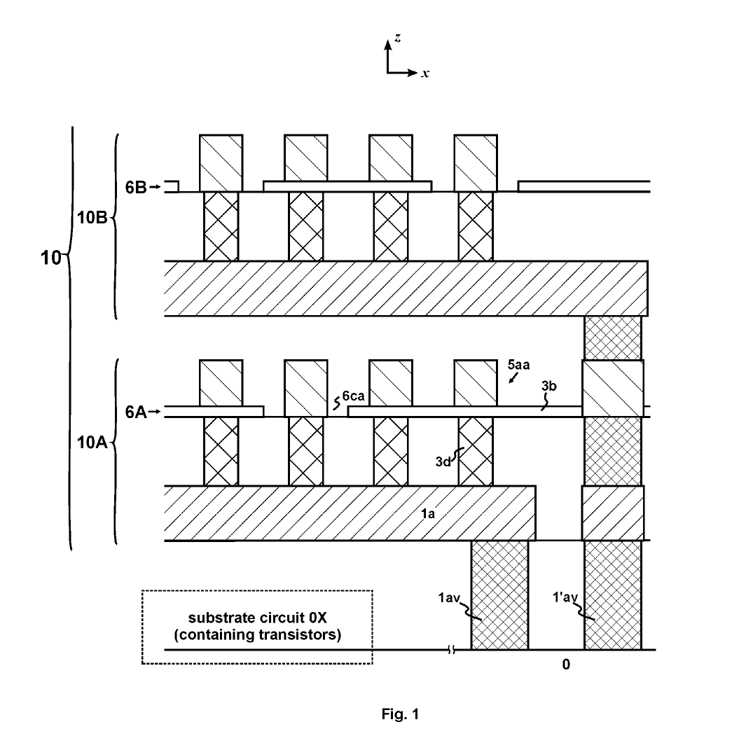

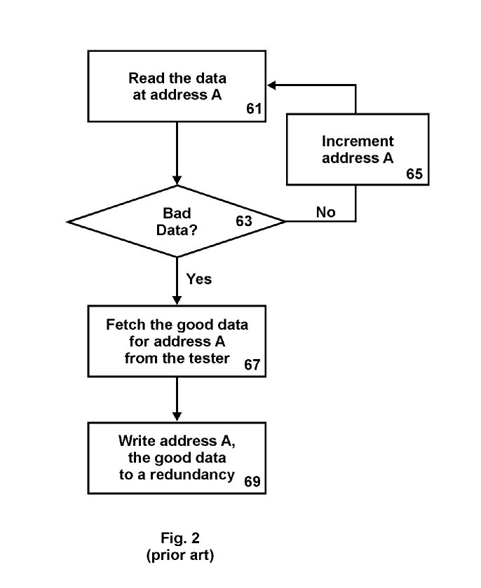

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

The present invention uses 3D-MPROM as an example to explain the concept of field-repair. The preferred embodiments disclosed herein can be extended to any large-capacity mask-ROM. A large-capacity mask-ROM can store GB-scale data, even TB-scale data. In the present invention, the primary data-recording means for a mask-ROM includes photo-lithography and imprint-lithography. The “mask” in the mask-ROM includes data-mask used in photo-lithography, as well as nano-imprint mold or nano-imprint template used in imprint-lithography.

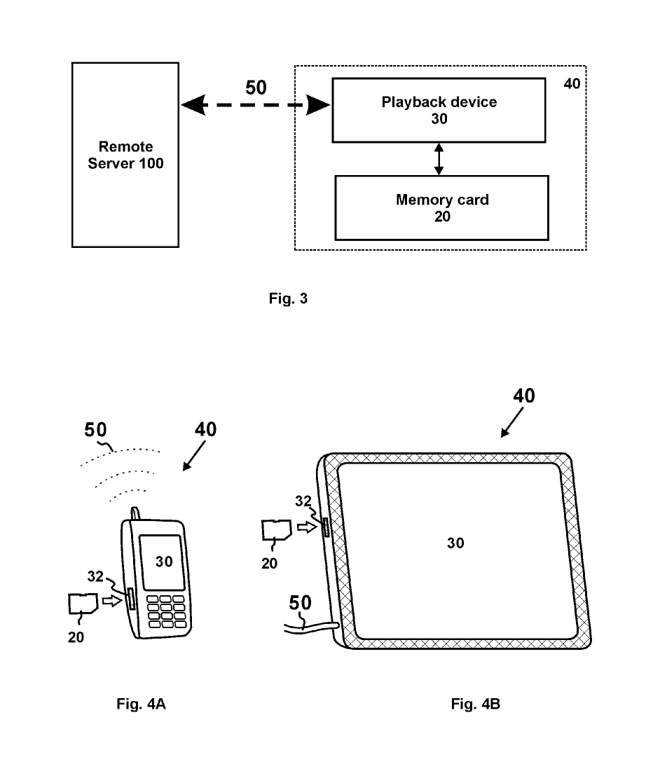

Referring now to FIG. 3, a field-repair system 40 and its communication channel 50 with a remoter server 100 are disclosed. The field-repair system 40 comprises a memory card 20 and a playback device 30. The memory card 20 could comprise a memory package or a memory module. It contains at least one 3D-MPROM die, more generally, at least a large-capacity mask-ROM die. The memory card 20 stores contents such as movies, video games, maps, music library, book library, and/or softwares.

The playback device 30, more generally, a consumer processing apparatus, can read and process data from the memory card 20, e.g., playing a movie or video game, reading a map, listening to music, reading books, or running software. The playback device 30 communicates with a remote server 100 through a communication channel 50. The remote server 100 stores a mass-content library, including a correct copy of the 3D-MPROM contents. The communication channel 50 includes internet, wireless local area network (WLAN, e.g., WiFi) and cellular (e.g., 3G, 4G) signals.

FIG. 4A illustrates a preferred playback device 30—a cellular phone. It communicates with the remote server 100 via cellular signals 50 and/or WiFi signals 50. The cellular phone 30 further comprises a slot 32 for holding the memory card 20, which can be inserted into or removed from the cellular phone 30. During the use of the cellular phone 30, the data in the memory card 20 will be checked and repaired. FIG. 4B illustrates another preferred playback device 30—an internet TV (or, a computer). It communicates with the remote server 100 via internet signals (including wired and wireless internet signals) 50. The internet TV (or, computer) 30 further comprises a slot 32 for holding the memory card 20, which can be inserted into or removed from the internet TV (or, computer) 30. During the use of the internet TV (or, computer) 30, the data in the memory card 20 will be checked and repaired.

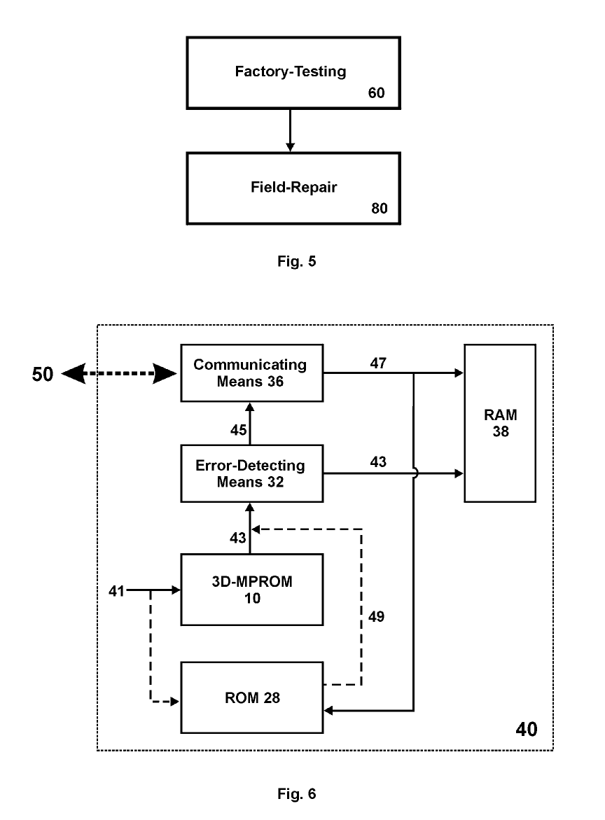

FIG. 5 discloses a preferred testing/repair method for the memory card 20. It comprises a factory-testing step 60 and a field-repair step 80. The factory-testing step 60 performs a basic test on the memory card 20 in factory, e.g., the integrity of its substrate circuit. At this step, most data in the memory card 20 are not checked, i.e. they are even not read out at all in factory! The factory-testing step 60 requires little testing time and incurs little testing cost.

The field-repair step 80 is carried out in the field where the playback device 30 is used. After the memory card 20 is inserted into the playback device 30, the 3D-MPROM data are checked and repaired in one of the following situations: 1) when the playback device 30 is idle (i.e. idle repair); 2) when the memory card 20 is in use, more particularly during its 1^{st} use (i.e. 1^{st}-use repair). In most cases, after it is repaired, the memory card 20 no longer needs to be repaired again. It can be directly used in other playback devices, e.g., the one that does not have internet access.

FIG. 6 discloses more details of the preferred field-repair system 40. It comprises a 3D-MPROM 10, a read-only memory (ROM) 28, an error-detecting means 32, a random-access memory (RAM) 38, and a communicating means 36. Details of these components will be explained in the following paragraphs.

The 3D-MPROM 10 stores the content data. The 3D-MPROM data should use a coding scheme that facilitates error detection. In the present invention, this coding scheme is referred to as error-detection code. Preferably, this error-detection code can be used to correct errors, too. Overall, the error-detection code should be stronger in error detection than error correction. Its examples include Reed-Solomon code, Golay code, BCH code, multi-dimensional parity code, Hamming code, and convolutional code.

The ROM 28 functions as a redundancy memory for the 3D-MPROM 10. It stores the addresses of the bad data from the 3D-MPROM 10 and the associated good data. The ROM 28 could be a non-volatile memory that can be programmed at least once, e.g., a one-time-programmable memory (OTP), an EPROM memory, an EEPROM memory, or a flash memory. The redundancy ROM 28 is preferably located in a same memory card 20 as the 3D-MPROM 10. This way, the repaired memory card 20 can be used by other playback devices (including those without internet access). To read a repaired memory card 20, address 41 is first compared with those stored in the redundancy ROM 28. If there is a match, the data 49 from the ROM 28, instead of the data 43 from the 3D-MPROM 10, are read out. This is indicated by the dash lines of FIG. 6.

The error-detecting means 32 detects errors in the data 43 from the 3D-MPROM 10. Preferably it can also correct error(s). This error-detecting means 32 should use an error-detecting algorithm suitable for the coding scheme used by the 3D-MPROM data. The error-detecting means 32 can be located either in the memory card 20 or in the playback device 30.

The RAM 38 is part of the playback device 30 and it functions as a buffer (or, cache) for the 3D-MPROM data that are to be used by the playback device 30. Because fetching good data from the remote server 100 to the playback device 30 causes a considerable latency, this buffer RAM 38 is used in the playback device 30 to eliminate the effect of this latency on the user's playback experience. During the field use of the 3D-MPROM, particularly during its 1^{st} use, a large amount of the RAM 38 is needed to buffer the 3D-MPROM data, because a virgin 3D-MPROM 10 may contain a large number of faulty memory cells.

The communicating means 36 is part of the playback device 30 and it provides communication between the playback device 30 and the remote server 100. Through the communication channel 50, the communicating means 36 fetches good data from the remote server 100. The communicating means 36 includes internet, wireless local network (WLAN, e.g., WiFi) and cellular communication means.

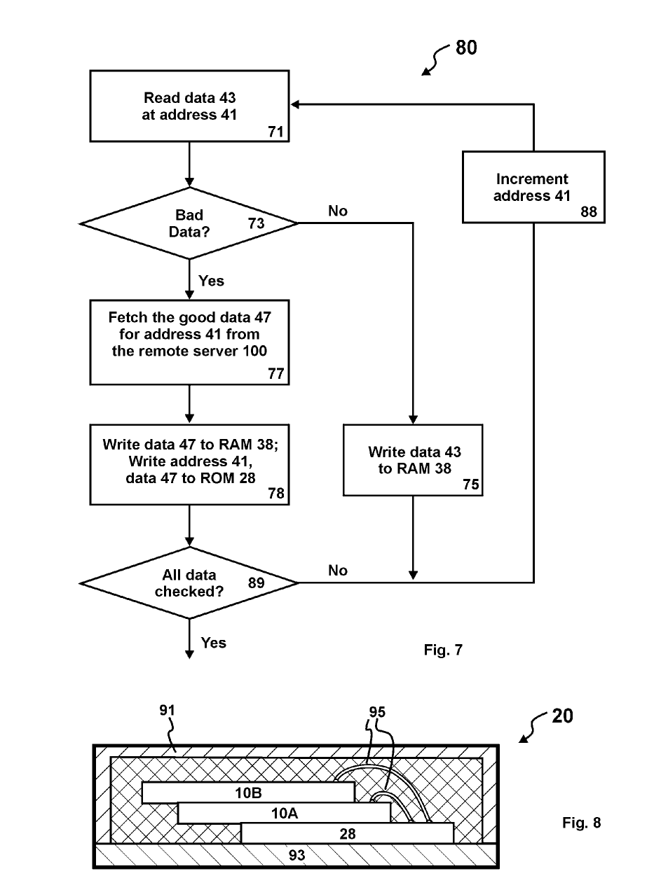

FIG. 7 is a flow chart showing a preferred field-repair method. It will be explained in combination of FIG. 6. First of all, the data 43 at address 41 are read out from the 3D-MPROM 10 (step 71). The error-detecting means 32 checks the data 43 (step 73). If no bad data are detected, the data 43 are written into the buffer RAM 38 (step 75). Otherwise, an error signal 45 is asserted and the good data 47 for the address 41 are fetched from the remote server 100 with the communicating means 50 (step 77). While the good data 47 are written into the buffer RAM 38, the good data 47 and the address 41 are also saved into the redundancy ROM 28 (step 78). In the present invention, the good data 47 and the address 41 are collectively referred to as redundancy information. These steps 71-78 are repeated for the incremented addresses 41 (step 88) until all data have been checked (step 89). Because bad data are only a small proportion of the total data stored in a 3D-MPROM, the field-repair step 80 needs a small bandwidth from the communicating channel 50.

FIG. 8 discloses a preferred 3D-MPROM card 20. It is a multi-die package and comprises a plurality of vertically stacked 3D-MPROM dice 10A, 10B and a redundancy ROM die 28. These dice 10A, 10B, 28 are located in a package housing 91 and stacked on a package substrate (e.g., an interposer) 93. Bond wires 95 provide electrical connection among the dice 10A, 10B, 28. In this preferred embodiment, a single redundancy ROM die 28 stores the redundancy information for a plurality of 3D-MPROM dice (e.g., 10A, 10B).

Besides mask-ROM, field-repair can be applied to any content memory. Hereinafter, a content memory is a semiconductor memory that stores at least a content. This content memory could be mask-ROM, one-time-programmable memory (OTP), EPROM, EEPROM and flash memory. During the course of its use in field, the content memory may suffer additional failures due to the aging of its memory cells. Accordingly, the present invention discloses a later-use repair. Although the content memory is repaired during the 1^{st} use, the later-use repair continues to monitor and repair the content data during the later uses. To be more specific, an error-detecting means checks the content data as they are read out from the content memory. When bad data are detected, the good data to replace the bad data are fetched from a remote server with a communicating means. Here, the remote server stores at least a correct copy of the content being read. Overall, field-repair is carried out whenever data are read out from the content memory. It ensures that the data processed by the playback device 30 are always good data.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A field-repair system for a three-dimensional mask-programmed read-only memory (3D-MPROM), comprising:
a 3D-MPROM comprising a plurality of vertically stacked memory cells;
an error-detecting means for detecting bad data from said 3D-MPROM, wherein said bad data cannot be corrected by any error-correction means in said 3D-MPROM;
a consumer processing apparatus comprising a communicating means with a remote device, said remote device storing a correct copy of the 3D-MPROM data;
wherein said consumer processing apparatus is configured to fetch good data to replace said bad data from said remote device with said communicating means.

2. The field-repair system according to claim 1, wherein said consumer processing apparatus is a cellular phone, an internet TV, or a computer.

3. The field-repair system according to claim 1, wherein said communicating means include internet, wireless local area network (WLAN) and cellular communication means.

4. The field-repair system according to claim 1, wherein the 3D-MPROM data use an error-detection code.

5. The field-repair system according to claim 1, further comprising a random-access memory (RAM) for buffering data from said 3D-MPROM.

6. The field-repair system according to claim 1, further comprising a read-only memory (ROM) for storing redundancy for said 3D-MPROM.

7. The field-repair system according to claim 6, wherein said 3D-MPROM and said ROM are located in a memory card.

8. The field-repair system according to claim 6, wherein said ROM stores redundancy for said 3D-MPROM dice.

9. A field-repair method for a three-dimensional mask-programmed read-only memory (3D-MPROM), comprising the steps of:
1) reading data from said 3D-MPROM, wherein said 3D-MPROM comprises a plurality of vertically stacked memory cells;
2) detecting bad data from said 3D-MPROM with an error-detection means, wherein said bad data cannot be corrected by any error-correction means in said 3D-MPROM;
3) fetching good data to replace said bad data from a remote device with a communicating means, wherein said remote device stores a correct copy of the 3D-MPROM data;
wherein the steps 1)-3) are carried out by a consumer processing apparatus comprising said communicating means.

10. The field-repair method according to claim 9, wherein said consumer processing apparatus is a cellular phone, an internet TV, or a computer.

11. The field-repair method according to claim 9, wherein said communicating means include internet, wireless local area network (WLAN) and cellular communication means.

12. The field-repair method according to claim 9, wherein the 3D-MPROM data use an error-detection code.

13. The field-repair method according to claim 9, further comprising the step of buffering the data from said 3D-MPROM in a random-access memory (RAM) after the step 1).

14. The field-repair method according to claim 9, further comprising the step of writing redundancy for said 3D-MPROM to a read-only memory (ROM) after the step 3).

15. A field-repair method for a semiconductor memory storing at least a content, comprising the steps of:
1) reading data from said semiconductor memory;
2) detecting bad data from said semiconductor memory, wherein said bad data cannot be corrected by any error-correction means in said semiconductor memory;
3) fetching good data to replace said bad data from a remote device with a communicating means, wherein said remote device stores a correct copy of said content;
wherein the steps 1)-3) are carried out by a consumer processing apparatus, and said consumer processing apparatus comprises said communicating means.

16. The field-repair method according to claim 15, wherein said semiconductor memory is a mask-programmed read-only memory (mask-ROM).

17. The field-repair method according to claim 16, wherein said mask-ROM is a three-dimensional mask-programmed read-only memory (3D-MPROM).

18. The field-repair method according to claim 15, wherein said semiconductor memory is selected from a group of memory including OTP, EPROM, EEPROM and flash memory.

19. The field-repair method according to claim 15, wherein said consumer processing apparatus is a cellular phone, an internet TV, or a computer.

20. The field-repair method according to claim 19, wherein said communicating means include internet, wireless local area network (WLAN) and cellular communication means.
